(19) United States
(12) Patent Application Publication
(10) Pub. No.: US 2026/0026071 A1
(43) Pub. Date: Jan. 22, 2026

(54) SPLIT-GATE STRUCTURE OF TRANSISTOR

(71) Applicant: Applied Materials, Inc., Santa Clara, CA (US)

(72) Inventors: Qintao ZHANG, Mt Kisco, NY (US); Sipeng GU, Lexington, MA (US)

(73) Assignee: Applied Materials, Inc., Santa Clara, CA (US)

(21) Appl. No.: 18/775,827

(22) Filed: Jul. 17, 2024

(51) Int. Cl. H01L 29/423; H01L 21/28; H01L 21/768; H01L 29/16; H01L 29/66; H01L 29/786

(52) U.S. Cl. CPC H10D 64/513; H01L 21/76883; H10D 30/023; H10D 30/6755; H10D 64/035; H10D 64/514; H10D 62/8325

(57) ABSTRACT

Disclosed herein are devices and methods for forming split-gate transistors. In some embodiments, a method may include forming a high-k dielectric layer within a trench of a transistor, and forming a bottom electrode within a lower portion of the trench, wherein the bottom electrode is formed over the high-k dielectric layer. The method may further include forming a low-k dielectric layer over the bottom electrode, and forming a gate material over the low-k dielectric layer.

### FIELD OF THE DISCLOSURE

The present embodiments relate to semiconductor device patterning and, more particularly, to a split-gate structure of a transistor.

### BACKGROUND OF THE DISCLOSURE

Trench metal-oxide-semiconductor field-effect transistor (MOSFET) scaling to improve device performance is a continuous goal. In some prior approaches, silicon carbide (SiC)-based trench MOSFETs include an implanted shielding layer to block a high electrical field from reaching a gate oxide of a bottom of the trench. However, as higher-power applications become the norm, and the cell pitch of the MOSFET decreases, the area consumed by the shielding layer limits total pitch scalability.

Accordingly, improved split-gate MOSFET approaches are needed to maximize scalability.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a method may include forming a high-k dielectric layer within a trench of a transistor, and forming a bottom electrode over the high-k dielectric layer, wherein the bottom electrode is formed within a lower portion of the trench. The method may further include forming a low-k dielectric layer over the bottom electrode, and forming a gate material over the low-k dielectric layer.

In another aspect, a method of forming a gate structure of a transistor may include forming a trench through a well and a source layer, wherein the source layer is formed over the well, forming a high-k dielectric layer within the trench, and forming a bottom electrode over the high-k dielectric layer, wherein the bottom electrode and the high-k dielectric layer are formed within a lower portion of the trench. The method may further include forming a low-k dielectric layer over the bottom electrode, and forming a gate material over the low-k dielectric layer.

In yet another aspect, a transistor may include a well and a source layer in an epitaxial layer, and a split gate structure formed in the well and the source layer. The split gate structure may include a high-k dielectric layer disposed over a bottom electrode, wherein the high-k dielectric layer and the bottom electrode are formed in a lower portion of a trench, and a low-k dielectric layer over the bottom electrode. The split gate structure may further include a gate material disposed over the low-k dielectric layer, wherein the gate dielectric and the gate material are formed in an upper portion of the trench.

### BRIEF DESCRIPTION OF THE DRAWINGS

The accompanying drawings illustrate exemplary approaches of the disclosure, including the practical application of the principles thereof, as follows:

FIG. 1 is a cross-sectional side view of a split-gate structure of a transistor, according to embodiments of the present disclosure;

FIG. 2 is a cross-sectional side view illustrating a transistor including a high-k dielectric layer formed within a plurality of trenches, according to embodiments of the present disclosure;

FIG. 3 is a cross-sectional side view illustrating the transistor including a bottom electrode formed atop the high-k dielectric layer within the plurality of trenches, according to embodiments of the present disclosure;

FIG. 4 is a cross-sectional side view illustrating the transistor following partial removal of the bottom electrode from the plurality of trenches, according to embodiments of the present disclosure;

FIG. 5 is a cross-sectional side view illustrating the transistor following partial removal of the high-k dielectric layer from the plurality of trenches, according to embodiments of the present disclosure;

FIG. 6 is a cross-sectional side view illustrating the transistor following formation of a low-k dielectric layer over the bottom electrode, according to embodiments of the present disclosure;

FIG. 7 is a cross-sectional side view illustrating the transistor following formation of a gate dielectric and a gate material over the low-k dielectric layer, according to embodiments of the present disclosure; and

FIG. 8 illustrates a schematic diagram of a processing apparatus according to embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods, devices, and systems in accordance with the present disclosure will now be described more fully hereinafter with reference to the accompanying drawings, where various embodiments are shown. The methods, devices, and systems may be embodied in many different forms and are not to be construed as being limited to the embodiments set forth herein. Instead, these embodiments are provided so the disclosure will be thorough and complete, and will fully convey the scope of the methods to those skilled in the art.

Embodiments described herein provide scalability of power transistors (e.g., MOSFET devices) without the use of a gate shielding layer under the gate trench. Advantageously, by using a split gate structure including a high-k dielectric constant liner along a lower portion of a trench and a low-k dielectric constant liner along an upper portion of the trench, an electrical field of the trench bottom dielectric is reduced without increasing capacitance of the top gate.

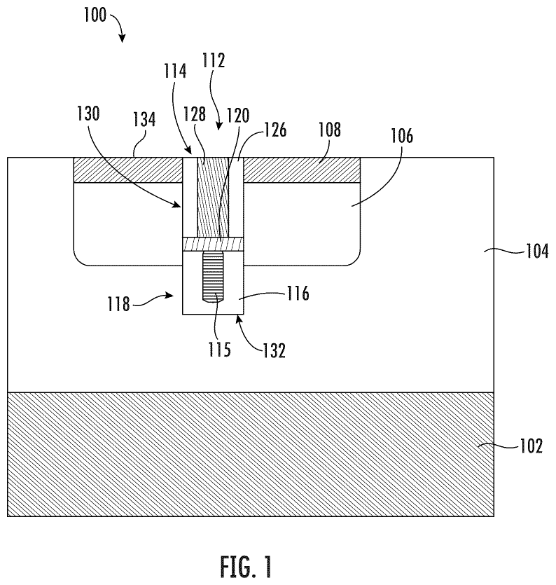

FIG. 1 is a side cross-sectional view of a semiconductor device structure (hereinafter “device”) 100, such as a split-gate silicon carbide (SiC) MOSFET, according to one or more embodiments described herein. The device 100 may correspond to a cell region having a drain 102, an epitaxial layer 104, a well 106, and a source region or layer 108. Although non-limiting, the epitaxial layer 104 may be a silicon carbide (SiC) n-type drift layer, the well 106 may be a p-type well, and the source layer 108 may be an N⁺ source layer. Shown as a single layer, the epitaxial layer 104 may include multiple layers in other embodiments. Although not shown, a substrate layer may be positioned between the epitaxial layer 104 and the drain 102.

As further shown, one or more trenches 112 may be formed through the epitaxial layer 104, the well 106, and the source layer 108. As will be described herein, a split-gate structure 114 may be formed within the trench 112. In some embodiments, the split-gate structure 114 may include a bottom electrode 115 formed within/over a high-k dielectric layer 116, wherein the bottom electrode 115 and the high-k dielectric layer 116 are formed in a lower portion 118 of the trench 112. Sometimes also referred to as a shield gate or as a split gate, the bottom electrode 115 is electrically connected to the source layer 108 (connection not shown). In some embodiments, the bottom electrode 115 may be a conductive material, such as polysilicon (doped or undoped). Although non-limiting, the high-k dielectric layer 116 may include one or more materials having a high dielectric constant (i.e., a dielectric constant greater than 4.0), such as hafnium (IV) oxide (HfO₂), zirconium dioxide (ZrO₂), aluminum oxide (Al₂O₃), barium strontium titanate (BST), lead zirconate titanate (PZT), zirconium silicate (ZrSiO₂), hafnium silicon dioxide (HfSiO₂), tantalum dioxide (TaO₂), and the like. As shown, the high-k dielectric layer 116 may be positioned directly adjacent the epitaxial layer 104 and the well 106.

A low-k dielectric layer 120 may be positioned over the bottom electrode 115 and the high-k dielectric layer 116. More specifically, the low-k dielectric layer 120 may be formed directly atop an upper surface 122 of the bottom electrode 115 and directly atop an upper surface 123 of the high-k dielectric layer 116. In some embodiments, the low-k dielectric layer 120 may be silicon dioxide (SiO2) or other similar material having a dielectric constant less than about 3.9.

As further shown, a gate dielectric 126 and a gate material 128 may be disposed over the low-k dielectric layer 116, wherein the gate dielectric 126 and the gate material 128 are formed in an upper portion 130 of the trench 112. Once formed, the gate material 128 may act as a control gate or gate electrode in the device 100. In some non-limiting embodiments, the gate dielectric 126 may be SiO2 and the gate material 128 may be a conductive material, such as polysilicon. As shown, the gate dielectric 126 and the gate material 128 may extend to an upper surface 134 of the source layer 108. Advantageously, the split-gate structure 114 with the high-k dielectric layer 116 along the lower portion 118 of the trench 112 and the low-k gate dielectric layer 126 along the upper portion 130 of the trench 112, reduces a dielectric electrical field at a bottom 132 of the trench 112, thus eliminating the need for a shielding layer within the epitaxial layer 104, beneath the split-gate structure 114.

Turning to FIG. 2, an approach for forming a split-gate MOSFET (hereinafter “device”) 200, which may be the same or similar as the device 100 described above, is shown. The device 200 includes a plurality of trenches 212 formed in one or more layers 204. Although not shown, the one or more layers 204 may include an epitaxial layer, a well, and a source region or layer formed over the well. Each of the plurality of trenches 212 includes a set of sidewalls 215 and a bottom surface 213, and may be formed by one or more blocking and vertical etch processes.

As further shown, a high-k dielectric layer 216 may be formed over the device 200, including within each of the trenches 212. More specifically, the high-k dielectric layer 216 may be conformally formed over the set of sidewalls 215 and the bottom surface 213 of the trenches 212, and directly over an upper surface 217 of the one or more layers 204. In various embodiments, the high-k dielectric layer 216 may be formed by a dielectric deposition process, such as chemical vapor deposition (CVD) or physical vapor deposition (PVD), or may be grown by an atomic layer deposition (ALD) process.

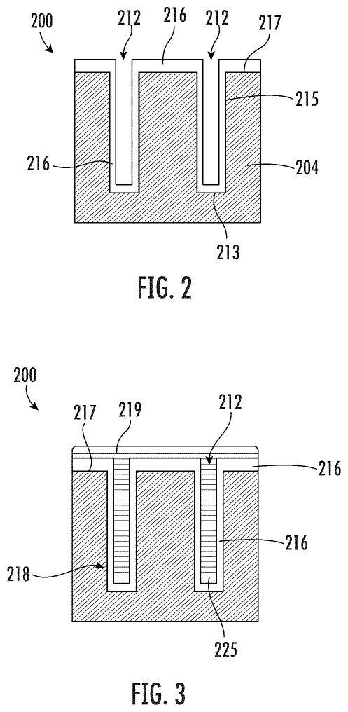

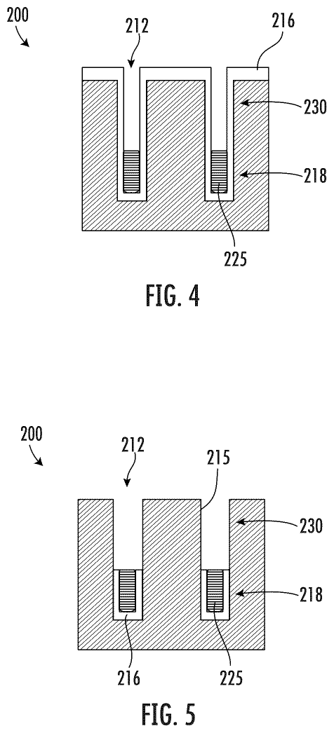

As shown in FIG. 3, a bottom electrode 225 may be formed within a lower portion 218 of the trenches 212 by depositing an electrode fill material 219 (e.g., polysilicon) within the trenches 212. The electrode fill material 219 may be further formed over the high-k dielectric layer 216 formed on the upper surface 217. The electrode fill material 219 may then be removed (e.g., etched) to partially remove the electrode fill material 219 from an upper portion 230 of the trenches 212, as shown in FIG. 4.

As shown in FIG. 5, the high-k dielectric layer 216 may then be partially removed from the device 200. More specifically, the high-k dielectric layer 216 may be removed from the upper surface 217 of the one or more layers 204 and from the set of sidewalls 215 in the upper portion 230 of the trenches 212. The bottom electrode 225 may serve as an etch stop layer to limit removal of the high-k dielectric layer 216. In some non-limiting embodiments, the high-k dielectric layer 216 is removed using a dry etch process.

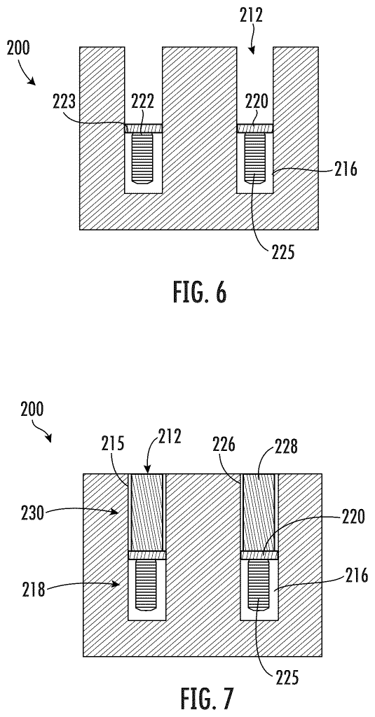

As shown in FIG. 6, a low-k dielectric layer 220 may be formed over the bottom electrode 225 and the high-k dielectric layer 216. More specifically, a low-k dielectric constant material may be formed directly atop an upper surface 222 of the bottom electrode 225 and directly atop an upper surface 223 of the high-k dielectric layer 216. In some embodiments, the low-k dielectric constant material may be SiO2, which is deposited within the trenches 212 and then etched back to a desired depth to form the low-k dielectric layer 220.

As shown in FIG. 7, a gate dielectric 226 and a gate material 228 may be formed over the low-k dielectric layer 216 within the trenches 212. More specifically, the gate dielectric 226 may be formed along the sidewalls 215 in the upper portion 230 of the trenches 212, and the gate material 228 may be formed directly atop the low-k dielectric layer 220. In some non-limiting embodiments, the gate dielectric 226 may be SiO2 and the gate material 228 may be a conductive material, such as polysilicon, which is deposited into the upper portion 230 of the trenches 212 and over the one or more layers 204 followed by a chemical mechanical polishing (CMP) to remove polysilicon from the upper surface 217. Although not shown, processing of the device 200 may then continue, e.g., by forming a plurality of contacts in the device 200, as known.

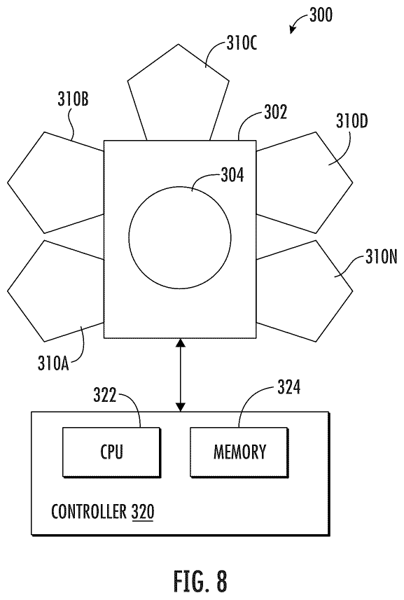

FIG. 8 shows a schematic of an example apparatus/system 300 according to embodiments of the disclosure. In some embodiments, the system 300 may be a cluster tool operable to perform processes necessary to form the devices described herein. Although non-limiting, the system 300 may include at least one central transfer station/chamber 302 and one or more robots 304 within the transfer station/chamber 302, wherein the robot 304 is operable to move a robot blade and a wafer to and from each of a plurality of processing chambers 310A-310N connected with, or positioned adjacent to, the transfer station/chamber 302. In some embodiments, the processing chambers 310A-310N may support various ion treatments, material deposition, material etching, and more. The particular arrangement of process chambers and components can be varied depending on the cluster tool, and should not be taken as limiting the scope of the disclosure. In another example, one or more of the chambers may include multiple process regions within a same chamber, which permits a common supply of gases, common pressure control, and common process gas exhaust/pumping. Modular design of the system enables rapid conversion from one configuration to any other.

In some embodiments, processing chamber 310A may be a deposition chamber, processing chamber 310B may be an etch chamber, and processing chamber 310C may house an ion processing tool. In some embodiments, processing chamber 310D may be operable to perform one or more thermal processes, such as an anneal.

A system controller 320 is in communication with the robot 304, the transfer station/chamber 302, and the plurality of processing chambers 310A-310N. The system controller 320 can be any suitable component that can control the processing chambers 310A-310N and robot(s) 304, as well as the processes occurring within the process chambers 310A-310N. For example, the system controller 320 can be a computer including a central processing unit 322, memory 324, suitable circuits/logic/instructions, and storage.

Processes or instructions may generally be stored in the memory 324 of the system controller 320 as a software routine that, when executed by the processor 322, causes the processing chambers 310A-310N to perform processes of the present disclosure. For example, the memory 324 may store instructions executable by the processor 322 to form a high-k dielectric layer within a trench of a transistor, form a bottom electrode within a lower portion of the trench, wherein the bottom electrode is formed over the high-k dielectric layer, form a low-k dielectric layer over the bottom electrode, and form a gate dielectric and a gate material over the low-k dielectric layer.

The software routine may also be stored and/or executed by a second processor (not shown) that is remotely located from the hardware being controlled by the processor 322. Some or all of the method(s) of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor 322, transforms the general-purpose computer into a specific purpose computer (controller) that controls the chamber operation such that the processes are performed.

In various embodiments, design tools can be provided and configured to create the datasets used to pattern the semiconductor layers of the device, e.g., as described herein. For example, data sets can be created to generate photomasks used during lithography operations to pattern the layers for structures as described herein. Such design tools can include a collection of one or more modules and can also be comprised of hardware, software or a combination thereof. Thus, for example, a tool can be a collection of one or more software modules, hardware modules, software/hardware modules or any combination or permutation thereof. As another example, a tool can be a computing device or other appliance running software, or implemented in hardware.

In sum, embodiments herein disclose a device and associated process flow for forming a split-gate MOSFET without a buried gate shielding layer. Advantageously, by providing a high-k gate dielectric in a lower portion of the trench, the gate electrical field can be reduced without increasing gate capacitance.

For the sake of convenience and clarity, terms such as “top,” “bottom,” “upper,” “lower,” “vertical,” “horizontal,” “lateral,” and “longitudinal” will be understood as describing the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporating the recited features.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

While certain embodiments of the disclosure have been described herein, the disclosure is not limited thereto, as the disclosure is as broad in scope as the art will allow and the specification may be read likewise. Therefore, the above description is not to be construed as limiting. Instead, the above description is merely as exemplifications of particular embodiments. Those skilled in the art will envision other modifications within the scope and spirit of the claims appended hereto.

What is claimed is:

1. A method, comprising:
forming a high-k dielectric layer within a trench of a transistor;
forming a bottom electrode over the high-k dielectric layer, wherein the bottom electrode is formed within a lower portion of the trench;
forming a low-k dielectric layer over the bottom electrode; and
forming a gate material of the transistor over the low-k dielectric layer.

2. The method of claim 1, wherein forming the trench comprises etching the trench through a well and through a source layer formed over the well.

3. The method of claim 2, wherein the trench is further etched into an epitaxial layer, and wherein the epitaxial layer is provided over a drain layer.

4. The method of claim 1, wherein forming the high-k dielectric layer within the trench comprises conformally forming the high-k dielectric layer along a sidewall and along a bottom surface of the trench, and wherein the bottom electrode is separated from the sidewall of the trench by the high-k dielectric layer.

5. The method of claim 1, further comprising forming a gate dielectric over the low-k dielectric layer, wherein the gate material is separated from a sidewall of the trench by the gate dielectric.

6. The method of claim 1, wherein forming the bottom electrode within the lower portion of the trench comprises:
depositing an electrode fill material within the trench; and
etching the electrode fill material to partially remove the electrode fill material from an upper portion of the trench.

7. The method of claim 1, wherein the low-k dielectric layer is formed from a first material having a dielectric constant of 3.9 or less, and wherein the high-k dielectric layer is formed from a second material having a dielectric constant of 4.0 or greater.

8. A method of forming a gate structure of a transistor, the method comprising:
forming a trench through a well and a source layer, wherein the source layer is formed over the well;
forming a high-k dielectric layer within the trench;
forming a bottom electrode over the high-k dielectric layer, wherein the bottom electrode and the high-k dielectric layer are formed within a lower portion of the trench;
forming a low-k dielectric layer over the bottom electrode; and
forming a gate material of the transistor over the low-k dielectric layer.

9. The method of claim 8, wherein the trench is further etched into an epitaxial layer, and wherein the epitaxial layer is provided over a drain layer.

10. The method of claim 8, wherein forming the high-k dielectric layer within the trench comprises conformally forming the high-k dielectric layer along a sidewall and along a bottom surface of the trench, and wherein the bottom electrode is separated from the sidewall of the trench by the high-k dielectric layer.

11. The method of claim 8, further comprising forming a gate dielectric over the low-k dielectric layer, wherein the gate material is separated from a sidewall of the trench by the gate dielectric.

12. The method of claim 8, wherein forming the bottom electrode within the lower portion of the trench comprises:
depositing an electrode fill material atop the high-k dielectric layer within the trench; and
etching the electrode fill material to partially remove the electrode fill material from an upper portion of the trench.

13. The method of claim 8, wherein the low-k dielectric layer is formed from a first material having a dielectric constant of 3.9 or less, and wherein the high-k dielectric layer is formed from a second material having a dielectric constant of 4.0 or greater.

14. The method of claim 13, wherein the first material comprises silicon dioxide, and wherein the second material comprises one of: aluminum oxide, hafnium oxide, or zirconium dioxide.

15. A transistor, comprising:
a well and a source layer in an epitaxial layer;
a split gate structure formed in the well and the source layer, wherein the split gate structure comprises:
a bottom electrode disposed over a high-k dielectric layer, wherein the high-k dielectric layer and the bottom electrode are formed in a lower portion of a trench;
a low-k dielectric layer over the bottom electrode; and
a gate electrode disposed over the low-k dielectric layer, wherein the gate electrode is formed in an upper portion of the trench.

16. The transistor of claim 15, further comprising a gate dielectric disposed over the low-k dielectric layer, wherein the gate electrode is separated from a sidewall of the trench by the gate dielectric.

17. The transistor of claim 15, wherein the low-k dielectric layer is disposed directly atop an upper surface of the bottom electrode and directly atop an upper surface of the high-k dielectric layer.

18. The transistor of claim 15, wherein the low-k dielectric layer is a first material having a dielectric constant of 3.9 or less, and wherein the high-k dielectric layer is a second material having a dielectric constant of 4.0 or greater.

19. The transistor of claim 15, wherein the high-k dielectric layer is disposed along a sidewall and along a bottom surface of the trench, and wherein the bottom electrode is separated from the sidewall of the trench by the high-k dielectric layer.

20. The transistor of claim 15, wherein no shielding layer is present in the epitaxial layer, beneath the split gate structure.
